(19) United States
(12) Patent Application Publication
(10) Pub. No.: US 2025/0081858 A1
(43) Pub. Date: Mar. 6, 2025

(54) DEVICE AND METHOD WITH RESONANCE FREQUENCY CONTROL

(71) Applicant: Samsung Electronics Co., Ltd., Suwon-si (KR)

(72) Inventors: Dae Yun KIM, Suwon-si (KR); Hyeok Shin KWON, Suwon-si (KR); In Su JEON, Suwon-si (KR)

(73) Assignee: Samsung Electronics Co., Ltd., Suwon-si (KR)

(21) Appl. No.: 18/602,554

(22) Filed: Mar. 12, 2024

(30) Foreign Application Priority Data
Aug. 30, 2023 (KR) 10-2023-0114873
Nov. 21, 2023 (KR) 10-2023-0162465

(51) Int. Cl. H10N 60/12

(52) U.S. Cl. CPC H10N 60/12; H10N 60/805

(57) ABSTRACT

A superconducting device includes a frequency-tunable device including a first conductive pad and a second conductive pad which are connected to each other by a Josephson junction, a ferromagnet having a magnetic domain wall, and a control circuit configured to apply a current to the ferromagnet to adjust a position of the magnetic domain wall of the ferromagnet, and to control a resonance frequency of the frequency-tunable device.

### CROSS-REFERENCE TO RELATED APPLICATION(S)

This application claims the benefit under 35 USC § 119 (a) of Korean Patent Application No. 10-2023-0114873 filed on Aug. 30, 2023 and No. 10-2023-0162465 filed on Nov. 21, 2023 in the Korean Intellectual Property Office, the entire disclosures of which are incorporated herein by reference for all purposes.

### BACKGROUND

### 1. Field

The following description relates to a device and method with resonance frequency control.

### 2. Description of the Related Art

A quantum computer may be a computational system that operates based on the principles of quantum mechanics, such as quantum superposition and quantum entanglement. A unit element capable of storing information by using the principles of quantum mechanics or the information itself is called quantum bit or qubit, which can be used as a basic unit of information in quantum computing.

The qubits may be implemented as various types of qubits, such as photonic qubits, ion trap qubits, topological qubits, superconducting qubits, superconducting qubits using superconducting materials, etc.

### SUMMARY

This summary is provided to introduce a selection of concepts in a simplified form that are further described below in the Detailed Description. This summary is not intended to identify key features or essential features of the claimed subject matter, nor is it intended to be used as an aid in determining the scope of the claimed subject matter.

In one or more general aspects, a superconducting device includes: a frequency-tunable device including a first conductive pad and a second conductive pad which are connected to each other by a Josephson junction; a ferromagnet having a magnetic domain wall; and a control circuit configured to apply a current to the ferromagnet to adjust a position of the magnetic domain wall of the ferromagnet, and to control a resonance frequency of the frequency-tunable device.

The frequency-tunable device may include either one or both of a tunable qubit and a tunable qubit coupler.

For the adjusting of the position of the magnetic domain wall, the control circuit may be configured to move the position of the magnetic domain wall of the ferromagnet by inducing a spin-transfer torque (STT) phenomenon.

For the inducing of the STT phenomenon, the control circuit may be configured to induce the STT phenomenon by applying the current, equal to or higher than a predetermined threshold value, in pulse form.

For the adjusting of the position of the magnetic domain wall, the control circuit may be configured to adjust the position of the magnetic domain wall to control the resonance frequency by using a model, which defines a relationship between the position of the magnetic domain wall and a magnetic flux passing through the frequency-tunable device, and a model which defines a relationship between the magnetic flux and the resonance frequency.

The frequency-tunable device may include two Josephson junctions, and the ferromagnet may be located outside one of the two Josephson junctions.

The ferromagnet may have a rectangular U-shape, with a portion of the ferromagnet being disposed between the first conductive pad and the second conductive pad.

The ferromagnet may be disposed at a bottom end of the Josephson junction and parallel to a longitudinal direction between the first conductive pad and the second conductive pad.

The ferromagnet may include any one or any combination of any two or more of Pt/Co/MgO, Pt/Co/AIOx, Pt/CoFeB/MgO, Pt/(Co/Ni)n, and Pt/(Co/Pt)n.

The first conductive pad and the second conductive pad may be made of a superconducting material.

The superconducting material may include any one or any combination of any two or more of aluminum (Al), Niobium (Nb), Indium (In), Alpha-Tantalum (α-Ta), Titanium (Ti), lead (Pb), Vanadium (V), and a compound thereof.

Either one or both of the first conductive pad and the second conductive pad may have a thickness of 50 nm to 400 nm.

The frequency-tunable device may be a transmon-type qubit.

The ferromagnet and the frequency-tunable device may be formed in a layered structure from bottom to top.

In one or more general aspects, a method of controlling a resonance frequency of a frequency-tunable device by using a superconducting device, the superconducting device comprising a frequency-tunable device including a first conductive pad and a second conductive pad which are connected to each other by a Josephson junction, and a ferromagnet having a magnetic domain wall, and the method includes: applying a current to the ferromagnet; adjusting a position of the magnetic domain wall; and controlling a resonance frequency.

The frequency-tunable device may include either one or both of a tunable qubit and a tunable qubit coupler.

The applying of the current may include applying the current, equal to or higher than a predetermined threshold value, in pulse form.

The adjusting of the position of the magnetic domain wall may include moving the position of the magnetic domain wall of the ferromagnet by inducing a spin-transfer torque (STT) phenomenon.

The controlling of the resonance frequency may include controlling the resonance frequency by using a model, which defines a relationship between the position of the magnetic domain wall and a magnetic flux passing through the frequency-tunable device, and a model which defines a relationship between the magnetic flux passing through the frequency-tunable device and the resonance frequency of the frequency-tunable device.

In one or more general aspects, a superconducting device includes: a frequency-tunable device comprising two Josephson junctions; and a ferromagnet having a magnetic domain wall, wherein a resonance frequency of the frequency-tunable device is a first frequency in response to the magnetic domain wall being located at a midpoint of a length of a surface of the ferromagnet, and the resonance frequency is a second frequency in response to the magnetic domain wall being located at an endpoint of the length of the surface.

Other features and aspects will be apparent from the following detailed description, the drawings, and the claims.

### BRIEF DESCRIPTION OF THE DRAWINGS

FIG. 1A is a diagram schematically illustrating a structure of a quantum computer chip according to one or more embodiments of the present disclosure.

FIG. 1B is a circuit diagram schematically illustrating a frequency-fixed device according to one or more embodiments of the present disclosure.

FIG. 1C is a circuit diagram schematically illustrating a frequency-tunable device according to one or more embodiments of the present disclosure.

FIG. 1D is a diagram explaining an example of controlling a resonance frequency of a frequency-tunable device according to one or more embodiments of the present disclosure.

FIGS. 2A and 2B are diagrams schematically illustrating a structure of a superconducting device including a frequency-tunable device according to one or more embodiments of the present disclosure.

FIG. 3 is a diagram explaining a ferromagnet having a magnetic domain wall according to one or more embodiments of the present disclosure.

FIGS. 4A to 4C are diagrams schematically illustrating a change in position of a magnetic domain wall caused by an applied current and a change in magnetic flux according to a change in position according to one or more embodiments of the present disclosure.

FIG. 5 is a graph showing a relationship between a position of a magnetic domain wall and a magnetic flux passing through a frequency-tunable device according to one or more embodiments of the present disclosure.

FIG. 6 is a graph showing a relationship between a magnetic flux and a resonance frequency according to one or more embodiments of the present disclosure.

FIGS. 7A to 7C are diagrams illustrating an example of manufacturing a superconducting device in a stacked or layered manner according to one or more embodiments of the present disclosure according to one or more embodiments of the present disclosure.

FIG. 8 is a flowchart illustrating a method of controlling a resonance frequency of a frequency-tunable device by using a superconducting device according to one or more embodiments of the present disclosure.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

In the following description, when an element is referred to as being “above” or “below” another element, it may be directly above or below the other element while being in contact with the other element, but it may also be above or below the element without contact with the other element.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

The steps of all methods described herein can be performed in any suitable order unless otherwise indicated herein or otherwise clearly contradicted by context. The use of any and all examples, or language (e.g., such as, etc.) provided herein, is intended merely to better illuminate the disclosure and does not pose a limitation on the scope of the disclosure unless otherwise claimed.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein.

Throughout the specification, when a component or element is described as “on,” “connected to,” “coupled to,” or “joined to” another component, element, or layer, it may be directly (e.g., in contact with the other component, element, or layer) “on,” “connected to,” “coupled to,” or “joined to” the other component element, or layer, or there may reasonably be one or more other components elements, or layers intervening therebetween. When a component or element is described as “directly on”, “directly connected to,” “directly coupled to,” or “directly joined to” another component element, or layer, there can be no other components, elements, or layers intervening therebetween. Likewise, expressions, for example, “between” and “immediately between” and “adjacent to” and “immediately adjacent to” may also be construed as described in the foregoing.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment (e.g., as to what an example or embodiment may include or implement) means that at least one example or embodiment exists where such a feature is included or implemented, while all examples are not limited thereto. The use of the terms “example” or “embodiment” herein have a same meaning (e.g., the phrasing “in one example” has a same meaning as “in one embodiment”, and “one or more examples” has a same meaning as “in one or more embodiments”).

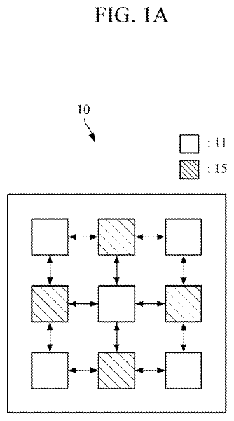

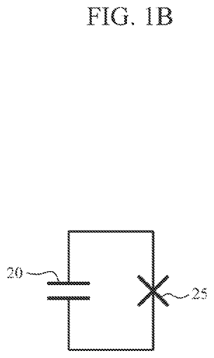

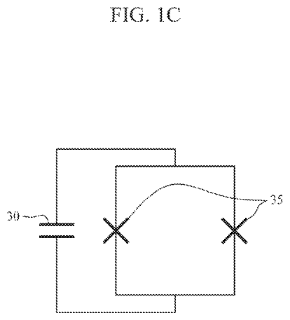

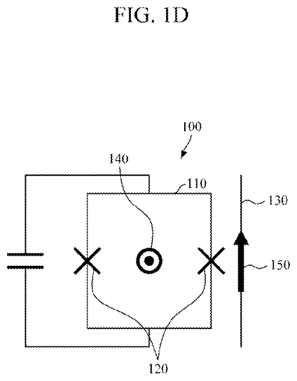

FIG. 1A is a diagram schematically illustrating a structure of a quantum computer chip according to one or more embodiments of the present disclosure. FIG. 1B is a circuit diagram schematically illustrating a frequency-fixed device (e.g., a fixed qubit or a fixed qubit coupler) according to one or more embodiments of the present disclosure, and FIG. 1C is a circuit diagram schematically illustrating a frequency-tunable device (e.g., a tunable qubit or a tunable qubit coupler) according to one or more embodiments of the present disclosure.

Referring to FIG. 1A, a quantum computer chip 10 may include a plurality of qubits 11 and qubit couplers 15 coupling the qubits. The qubit couplers 15 may be used for quantum entanglement induced by qubit-qubit interactions, etc., and two or more qubits 11 may be included in the quantum computer chip 10 such that the qubit couplers 15 may be used for qubit-qubit interactions.

The qubits 11 may be divided into two types: fixed qubit with a resonance frequency fixed at a specific value, and frequency-tunable device with a tunable resonance frequency. The qubit couplers 15 may also be divided into two types: fixed qubit coupler with a resonance frequency fixed at a specific value, and frequency-tunable device coupler with a tunable resonance frequency.

The fixed qubit and the fixed qubit coupler may be composed of, for example, one capacitor 20 and one Josephson junction 25 (e.g., as shown in FIG. 1B), and the frequency-tunable device and the frequency-tunable device coupler may be composed of, for example, one capacitor 30 and two Josephson junctions 35 (e.g., as shown in FIG. 1C).

That is, the qubits and couplers may have the same structure, such that either the qubit or the coupler may be selected depending on the purpose of use.

The frequency-tunable device may be tuned to a desired or determined resonance frequency by adjusting the resonance frequency, and the frequency-tunable device coupler may be tuned to two different resonant frequencies for on/off control of quantum entanglement between qubits.

An example of setting a desired resonance frequency by applying a current to a ferromagnet will be described below based on the tunable qubit.

FIG. 1D is a diagram explaining an example of controlling a resonance frequency of a frequency-tunable device.

Referring to FIG. 1D, a frequency-tunable device 100 may include a superconducting quantum interface device (SQUID) 110 including two Josephson junctions 120, and may use a separate control line 130 adjacent to the qubit in order to apply a local magnetic field to the qubit.

When a control current 150 is applied to the control line 130, a magnetic field may be formed around the control line 130, and the formed magnetic field may change a magnetic flux 140 passing through the SQUID. The magnetic flux 140 passing through the SQUID may cause a change in critical current of the Josephson junction. The resonance frequency of the qubit is determined by the critical current of the Josephson junctions 120, such that the resonance frequency of the qubit may be controlled by adjusting the control current 150 applied to the control line 130.

However, the typical frequency-tunable device 100 has drawbacks in that a continuous application of the control current may be required during the operation of the qubit, a separate cryogenic electronic device may be required to apply a direct current (DC) through the control line, and magnetic noise (flux noise) and crosstalk caused by DC current may disrupt stable quantum computing.

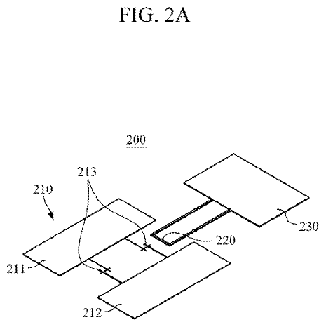

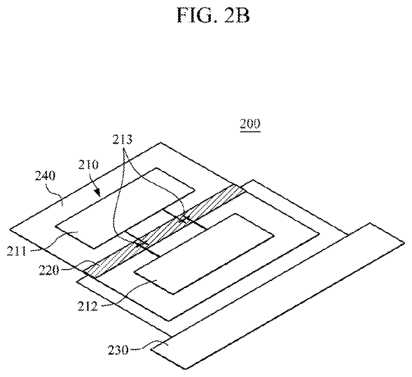

FIGS. 2A and 2B are diagrams schematically illustrating a structure of a superconducting device including a frequency-tunable device according to one or more embodiments of the present disclosure.

Referring to FIG. 2A, a superconducting device 200 may include a frequency-tunable device 210, a ferromagnet 220, and a control circuit 230.

The frequency-tunable device 210 may be a qubit with a tunable resonance frequency, and may include a first conductive pad 211 and a second conductive pad 212 which are connected to each other by two Josephson junctions 213.

The Josephson effect may be a phenomenon when the electric current flows through a thin insulator sandwiched between, e.g., two superconductors. The Josephson junction 213 may consist of two superconductors weakly linked by an insulator. In this example, in order to create the Josephson junction 213, not only the insulator but also various types of metals may be used for the weak link in the Josephson junction 213.

The first conductive pad 211 and the second conductive pad 212 may be made of superconducting materials. In this example, the first conductive pad 211 and the second conductive pad 212 may be made of the same superconducting material or different superconducting materials. The superconducting material may include at least one of aluminum (Al), Niobium (Nb), Indium (In), Alpha-Tantalum (α-Ta), Titanium (Ti), lead (Pb), Vanadium (V), and a compound thereof (e.g., NbN, NbTiN, TiN, or VN), but is not limited thereto.

In order to have superconductivity, the pads may have a thickness that is greater than or equal to a first value and less than or equal to a second value, such that the first conductive pad 211 and the second conductive pad 212 may be formed with a thickness of, for example, 50 nm to 400 nm. The thickness of the first conductive pad 211 and the second conductive pad 212 is not limited thereto.

The ferromagnet 220 may be disposed at a predetermined distance from the frequency-tunable device 210.

The ferromagnet may refer to a material in which the magnetic moment or magnetization of atoms is aligned in a specific direction even in the absence of an external magnetic field. The magnetizations of the ferromagnet may have a preferred direction of alignment, which is called magnetic anisotropy. For example, in a ferromagnetic thin film, when the ferromagnetic thin film has perpendicular magnetic anisotropy, the magnetization of the ferromagnet may prefer to be aligned in a vertical direction (e.g., +Z or −Z axis direction) of the ferromagnetic thin film. When the ferromagnetic thin film has in-plane magnetic anisotropy, the magnetization of the ferromagnet may prefer to be aligned in a plane direction (e.g., XY plane direction) of the ferromagnetic thin film. The ferromagnet may have a heterojunction structure with a heavy metal (e.g., Pt, Ta, W), a ferromagnet (e.g., Co, CoFeB, (CoNi)n, (CoPt)n), and an insulator (e.g., MgO, AlOx, TaOx), and may include, for example, at least one of Pt/Co/MgO, Pt/Co/AIOx, Pt/CoFeB/MgO, Pt/(Co/Ni)n, and Pt/(Co/Pt)n.

In this example, the ferromagnet may include a magnetic domain wall.

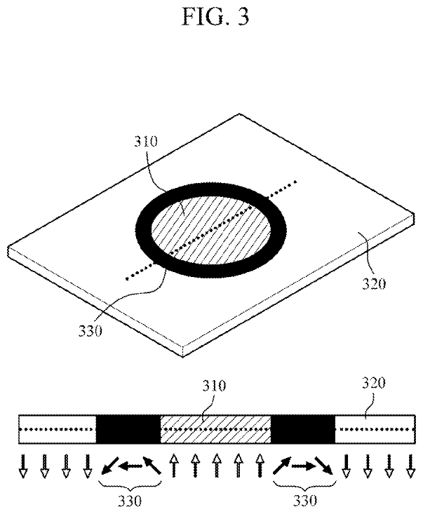

FIG. 3 is a diagram explaining a ferromagnet having a magnetic domain wall according to one or more embodiments of the present disclosure. While FIG. 3 illustrates an example of a ferromagnet having perpendicular magnetic anisotropy, the embodiment is not limited thereto.

The magnetization of the ferromagnet may prefer to be aligned in an upward or downward direction due to perpendicular magnetic anisotropy, and may have the property that magnetizations aligned in an upward direction are gathered as upward magnetizations, and magnetizations aligned in a downward direction are gathered as downward magnetizations, and a region where the magnetizations aligned in the same direction are gathered together is called a magnetic domain.

Referring to FIG. 3, by applying a predetermined external magnetic field to a ferromagnet, an up magnetic domain 310 in which magnetizations are aligned in an upward direction and a down magnetic domain 320 in which magnetizations are aligned in a downward direction are created, such that a magnetic domain wall 330 may be created which is a boundary surface between the up magnetic domain 310 and the down magnetic domain 320. In this example, a thickness of the magnetic domain wall 330 may be, for example, in a range of several angstroms to several tens of nanometers, but is not limited thereto. In addition, considering the characteristics of the ferromagnet, the created magnetic domain wall 330 may remain the same even when the external magnetic field disappears, and depending on the type of ferromagnet, the magnetic domain wall 330 may be moved only by applying a magnetic field greater than or equal to a predetermined critical value.

Referring back to FIG. 2A, the ferromagnet 220 may be disposed outside any one of the two Josephson junctions 213, and the ferromagnet 220 may have a rectangular U-shape, with a portion thereof being disposed between the first conductive pad 211 and the second conductive pad 212. A shape of the ferromagnet 220 is not limited thereto, and the ferromagnet 220 may be spaced apart from each of the first conductive pad 211, the second conductive pad 212, and the Josephson junctions 213 by a distance of, for example, several micrometers (μm) to several tens of micrometers (μm), which may be distance that causes a change in magnetic flux of the frequency-tunable device 210.

In another embodiment, referring to FIG. 2B, the ferromagnet 220 may also be disposed at a bottom end of the Josephson junction of the frequency-tunable device 210 formed on the substrate 240, and may be disposed parallel to a longitudinal direction between the first conductive pad 211 and the second conductive pad 212. However, the arrangement of the ferromagnet 220 is not limited hereto.

The control circuit 230 may apply a current to the ferromagnet 220, and may control a resonance frequency of the frequency-tunable device 210 based on the current. For example, by applying a current to the ferromagnet 220 to adjust a position of the magnetic domain wall of the ferromagnet 220, the control circuit 230 may control the resonance frequency of the frequency-tunable device 210.

In this example, by directly applying a current to the ferromagnet 220 to induce a spin-transfer torque (STT) phenomenon, the control circuit 230 may move the position of the magnetic domain wall of the ferromagnet 220.

The spin-transfer torque (STT) may be a phenomenon in which when a spin direction of conduction electrons injected into a magnetic material (e.g., ferromagnetic material) is not parallel to a magnetization direction of the magnetic material, the spin angular momentum of the conduction electrons is transferred to the magnetic moment of the magnetic material, thereby changing the magnetization direction of the magnetic material. The spin-transfer torque (STT) generated by the applied current may allow the magnetic domain wall, formed in the magnetic material, to move in a direction of the current or in an opposite direction of the current.

The control circuit 230 may induce the STT phenomenon by applying a current, equal to or higher than a threshold value, in pulse form to the ferromagnet 220. The magnetization of the ferromagnet 220 may remain the same even when the external magnetic field disappears, such that the control circuit 230 may apply the current only once without need to continuously apply the current equal to or higher than the threshold value, and may apply the current only once, for example, in pulse form.

The control circuit 230 may adjust the position of the magnetic domain wall in order to control the resonance frequency by using a model that defines a relationship between the position of the magnetic domain wall based on the applied current and a magnetic flux passing through the frequency-tunable device, and a model that defines a relationship between the magnetic flux and the resonance frequency.

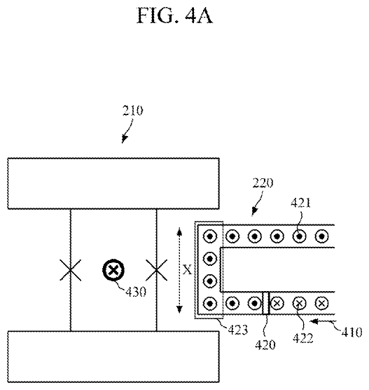

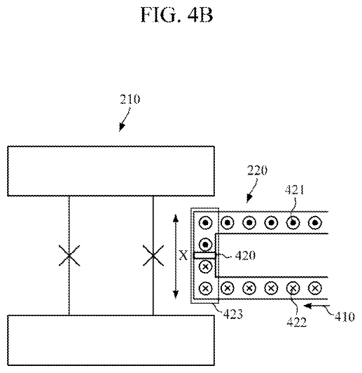

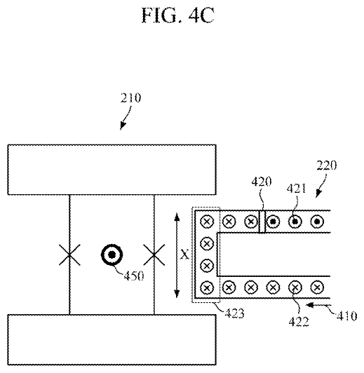

FIGS. 4A to 4C are diagrams schematically illustrating a change in position of a magnetic domain wall caused by an applied current and a change in magnetic flux according to a change in position according to one or more embodiments of the present disclosure.

Referring to FIGS. 4A to 4C, a magnetic domain wall 420 is located at a boundary between an up magnetic domain 421, in which magnetizations are aligned in a vertical upward direction, and a down magnetic domain 422 in which the magnetizations are aligned in a vertical downward direction.

When a control current 410 is applied to the ferromagnet 220, the magnetic domain wall 420 may be moved, for example, in the direction of the current by the STT phenomenon, and a magnetic flux 430 passing through the frequency-tunable device 210 may be changed by the movement of the magnetic domain wall 420.

Referring to FIG. 4A, when a position of the magnetic domain wall 420 is set by the control current 410 so that one surface 423 of the ferromagnet 220, which is closest to the frequency-tunable device 210, is formed to have only the up magnetic domain 421, a magnetic field (e.g., stray field) generated by the ferromagnet 220 moves along a parabolic path in which the magnetic field is directed from the N-pole on the top to the S-pole on the bottom of a permanent magnet, thereby generating a magnetic flux 430 in the frequency-tunable device 210 in the vertical downward direction (e.g., as per Ampere's right-handed screw rule).

Referring to FIG. 4B, when a position of the magnetic domain wall 420 is set in the middle of the one surface 423 by the control circuit 410 so that the up magnetic domain 421 and the down magnetic domain 422 may be formed with the same size on one surface 423 of the ferromagnet 220, which is closest to the frequency-tunable device 210, the magnetic field generated by the ferromagnet 220 may not generate a magnetic flux in the frequency-tunable device 210.

Referring to FIG. 4C, when the magnetic domain wall 420 is set by the control circuit 410 so that the one surface 423 of the ferromagnet 220, which is closest to the frequency-tunable device 210, is formed to have only the down magnetic domain 422, a magnetic field generated by the ferromagnet 220 moves along a parabolic path in which the magnetic field is directed from the N-pole on the bottom to the S-pole on the top of a permanent magnet, thereby generating a magnetic flux 450 in the frequency-tunable device 210 in the vertical upward direction.

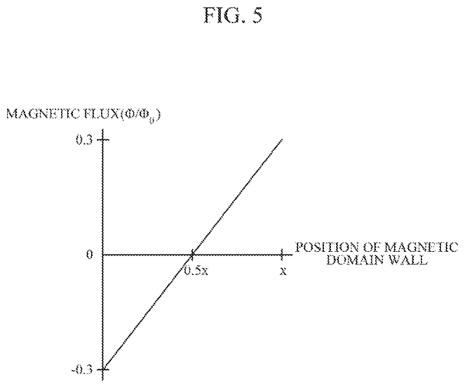

As illustrated in FIGS. 4A to 4C, a model that defines a relationship between the position of the magnetic domain wall and the magnetic flux may be generated and may be represented by a graph in FIG. 5.

FIG. 5 is a graph showing a relationship between a position of a magnetic domain wall and a magnetic flux passing through a frequency-tunable device according to one or more embodiments of the present disclosure. Referring to FIGS. 4A to 4C and FIG. 5, when the one surface 423 of the ferromagnet 220, which is closest to the frequency-tunable device 210, has a length of X, when the magnetic domain wall 420 is located at a midpoint 0.5X, the magnetic flux becomes 0, and when the magnetic domain wall 420 is located at an end point (e.g., 0 or X) of one surface, the magnetic flux is minimized or maximized (e.g., respectively).

By obtaining the magnetic flux using the model by adjusting the position of the magnetic domain wall based on the current applied by the control circuit 230, a resonance frequency of the frequency-tunable device may be finally obtained by using a model that defines a relationship between a predefined magnetic flux and the resonance frequency.

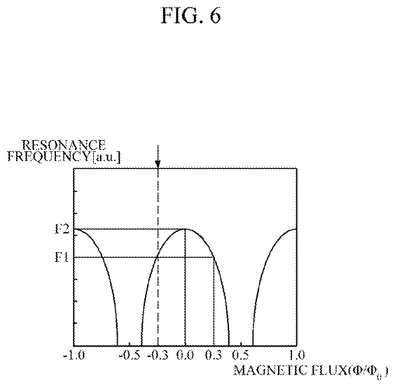

FIG. 6 is a graph showing a relationship between a magnetic flux and a resonance frequency according to one or more embodiments of the present disclosure.

Referring to FIG. 6, when a magnetic flux Φ/Φₒ is −0.3 or 0.3 (FIG. 4A or 4C) which is obtained when the magnetic domain wall 420 is located, for example, at the end of the one surface 423 of the ferromagnet 220, the resonance frequency corresponds to a first frequency F1, and when a magnetic flux is 0 (FIG. 4B) which is obtained when the magnetic domain wall 420 is located at the midpoint of the ferromagnet 220, the resonance frequency corresponds to a second frequency F2.

The typical frequency-tunable device may be operated by a volatile control method, which is inefficient since it a control current may need to be continuously applied in order to maintain a desired resonance frequency, and noise (e.g., 1/f noise) caused by the control current may reduce the reliability of the measured resonance frequency. In addition, for the typical frequency-tunable device, a separate cryogenic electronic device (e.g., cryogenic DC line) may also be required to supply the control current.

In contrast to the typical frequency-tunable device, in one or more embodiments in which a resonance frequency of the frequency-tunable device is controlled by adjusting a position of the magnetic domain wall of a ferromagnet based on the applied current, the resonance frequency may be controlled by applying a current equal to or higher than a threshold value once (non-volatile control method) without continuously applying the current, given the characteristics of the ferromagnet that even when an external magnetic field disappears, the magnetization remains the same and the position of the magnetic domain wall also remains in place. In addition, a control line for applying a current, which is essential for the typical frequency-tunable device, is not required such that noise does not occur due to the control current, with no cost problem due to a separate electronic device, and allowing relatively stable control of the resonance frequency.

In another embodiment, the frequency-tunable device 210 may be a transmon-type qubit. The transmon-type qubit is a qubit designed to have a high ratio of the Josephson energy to the charge energy in order to reduce sensitivity to charge noise, and the Josephson junction is formed with an insulator sandwiched between two shunt capacitors corresponding to the first conductive pad and the second conductive pad which are formed of superconductors.

As described above, the tunable qubit and the tunable qubit coupler, which are frequency-tunable devices, may have the same structure, such that either the qubit or the coupler may be selected depending on the purpose of use. Thus, the tunable qubit in the above embodiment may also be used as the tunable qubit coupler.

For example, on/off switching of the resonance frequency of the tunable qubit coupler may be controlled by placing a ferromagnet adjacent to the tunable qubit coupler, and by applying a current to the ferromagnet through a control circuit and adjusting a position of the magnetic domain wall.

While FIG. 2A illustrates an example in which the superconducting device including the frequency-tunable device is formed in one layer, the superconducting device may be formed in multiple layers that are stacked on top of each other. For example, the ferromagnet and the frequency-tunable device may be stacked from bottom to top.

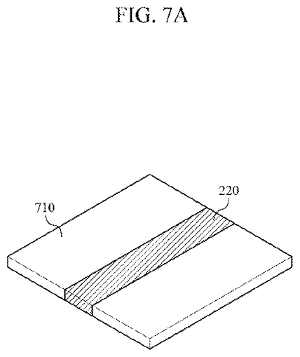

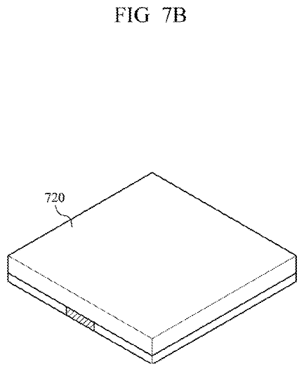

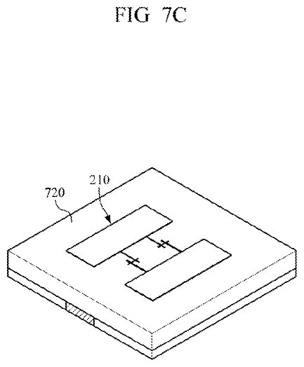

FIGS. 7A to 7C are diagrams illustrating an example of manufacturing the superconducting device of FIG. 2B in a stacked or layered manner according to one or more embodiments of the present disclosure.

Referring to FIGS. 7A to 7C, a ferromagnet 220 is first disposed on a substrate 710 (FIG. 7A). Then, an insulating layer 720 made of an insulating material is disposed thereon, and lastly, the frequency-tunable device 210 is disposed thereon (FIG. 7C).

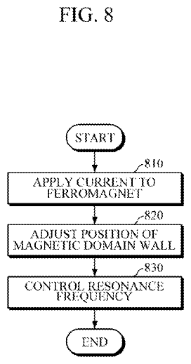

FIG. 8 is a flowchart illustrating a method of controlling a resonance frequency of a frequency-tunable device by a superconducting device according to one or more embodiments of the present disclosure. Operations 810 to 840 described below may be performed in the order and manner as shown and described below with reference to FIG. 8, but the order of one or more of the operations may be changed, one or more of the operations may be omitted, and/or two or more of the operations may be performed in parallel or simultaneously without departing from the spirit and scope of the example embodiments described herein.

FIG. 8 is an example of a method of controlling a resonance frequency of the frequency-tunable device according to the embodiment of FIG. 7C, which is described in detail above, and thus will be briefly described below in order to avoid redundancy.

In this example, the superconducting device may include the frequency-tunable device including the first conductive pad and the second conductive pad which are connected to each other by two Josephson junctions, and the ferromagnet including the magnetic domain wall. The ferromagnet may be located outside one of the two Josephson junctions, and may be disposed at a bottom end of the Josephson junction and is disposed parallel to a longitudinal direction between the first conductive pad and the second conductive pad.

The superconducting device may apply a current to the ferromagnet in 810. In this case, the superconducting device may apply a current, equal to or higher than a predetermined threshold value, in pulse form. The magnetization of the ferromagnet may remain the same even when the external magnetic field disappears, such that a continuous application of the current equal to or higher than the predetermined critical value is not needed, and instead the superconducting device may apply the current only once, for example, in pulse form.

When the current is applied to the ferromagnet in 810, the superconducting device may adjust a position of the magnetic domain wall in 820. In this example, the superconducting device may move the position of the magnetic domain wall in the ferromagnet by inducing a spin-transfer torque (STT) phenomenon.

When the position of the magnetic domain wall is adjusted in 820, the superconducting device may control the resonance frequency in 830. The superconducting device may control the resonance frequency by using a model, which defines a relationship between the position of the magnetic domain wall and a magnetic flux passing through the frequency-tunable device, and a model which defines a relationship between the magnetic flux passing through the frequency-tunable device and the resonance frequency of the frequency-tunable device.

The quantum computer chips, qubits, qubit couplers, capacitors, Josephson junctions, frequency-tunable devices, SQUIDs, control lines, superconducting devices, ferromagnets, control circuits, first conductive pads, second conductive pads, substrates, insulating layers, quantum computer chip 10, qubits 11, qubit couplers 15, capacitor 20, Josephson junction 25, capacitor 30, Josephson junctions 35, frequency-tunable device 100, SQUID 110, Josephson junctions 120, control line 130, superconducting device 200, frequency-tunable device 210, ferromagnet 220, control circuit 230, first conductive pad 211, second conductive pad 212, Josephson junctions 213, substrate 240, substrate 710, and insulating layer 720 described herein, including descriptions with respect to respect to FIGS. 1-8, are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in, and discussed with respect to, FIGS. 1-8 that perform the operations described in this application are performed by computing hardware, for example, by one or more processors or computers, implemented as described above implementing instructions (e.g., computer or processor/processing device readable instructions) or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A superconducting device comprising:
a frequency-tunable device including a first conductive pad and a second conductive pad which are connected to each other by a Josephson junction;
a ferromagnet having a magnetic domain wall; and
a control circuit configured to apply a current to the ferromagnet to adjust a position of the magnetic domain wall of the ferromagnet, and to control a resonance frequency of the frequency-tunable device.

2. The superconducting device of claim 1, wherein the frequency-tunable device comprises either one or both of a tunable qubit and a tunable qubit coupler.

3. The superconducting device of claim 2, wherein, for the adjusting of the position of the magnetic domain wall, the control circuit is configured to move the position of the magnetic domain wall of the ferromagnet by inducing a spin-transfer torque (STT) phenomenon.

4. The superconducting device of claim 3, wherein, for the inducing of the STT phenomenon, the control circuit is configured to induce the STT phenomenon by applying the current, equal to or higher than a predetermined threshold value, in pulse form.

5. The superconducting device of claim 3, wherein, for the adjusting of the position of the magnetic domain wall, the control circuit is configured to adjust the position of the magnetic domain wall to control the resonance frequency by using a model, which defines a relationship between the position of the magnetic domain wall and a magnetic flux passing through the frequency-tunable device, and a model which defines a relationship between the magnetic flux and the resonance frequency.

6. The superconducting device of claim 2, wherein
the frequency-tunable device comprises two Josephson junctions, and
the ferromagnet is located outside one of the two Josephson junctions.

7. The superconducting device of claim 1, wherein the ferromagnet has a rectangular U-shape, with a portion of the ferromagnet being disposed between the first conductive pad and the second conductive pad.

8. The superconducting device of claim 1, wherein the ferromagnet is disposed at a bottom end of the Josephson junction and parallel to a longitudinal direction between the first conductive pad and the second conductive pad.

9. The superconducting device of claim 1, wherein the ferromagnet comprises any one or any combination of any two or more of Pt/Co/MgO, Pt/Co/AlOx, Pt/CoFeB/MgO, Pt/(Co/Ni) n, and Pt/(Co/Pt) n.

10. The superconducting device of claim 1, wherein the first conductive pad and the second conductive pad are made of a superconducting material.

11. The superconducting device of claim 1, wherein the superconducting material comprises any one or any combination of any two or more of aluminum (Al), Niobium (Nb), Indium (In), Alpha-Tantalum (α-Ta), Titanium (Ti), lead (Pb), Vanadium (V), and a compound thereof.

12. The superconducting device of claim 1, wherein either one or both of the first conductive pad and the second conductive pad has a thickness of 50 nm to 400 nm.

13. The superconducting device of claim 2, wherein the frequency-tunable device is a transmon-type qubit.

14. The superconducting device of claim 1, wherein the ferromagnet and the frequency-tunable device are formed in a layered structure from bottom to top.

15. A method of controlling a resonance frequency of a frequency-tunable device by using a superconducting device, the superconducting device comprising a frequency-tunable device including a first conductive pad and a second conductive pad which are connected to each other by a Josephson junction, and a ferromagnet having a magnetic domain wall, and the method comprising:
applying a current to the ferromagnet;
adjusting a position of the magnetic domain wall; and
controlling a resonance frequency.

16. The method of claim 15, wherein the frequency-tunable device comprises either one or both of a tunable qubit and a tunable qubit coupler.

17. The method of claim 16, wherein the applying of the current comprises applying the current, equal to or higher than a predetermined threshold value, in pulse form.

18. The method of claim 16, wherein the adjusting of the position of the magnetic domain wall comprises moving the position of the magnetic domain wall of the ferromagnet by inducing a spin-transfer torque (STT) phenomenon.

19. The method of claim 16, wherein the controlling of the resonance frequency comprises controlling the resonance frequency by using a model, which defines a relationship between the position of the magnetic domain wall and a magnetic flux passing through the frequency-tunable device, and a model which defines a relationship between the magnetic flux passing through the frequency-tunable device and the resonance frequency of the frequency-tunable device.

20. A superconducting device comprising:
a frequency-tunable device comprising two Josephson junctions; and
a ferromagnet having a magnetic domain wall,
wherein a resonance frequency of the frequency-tunable device is a first frequency in response to the magnetic domain wall being located at a midpoint of a length of a surface of the ferromagnet, and the resonance frequency is a second frequency in response to the magnetic domain wall being located at an endpoint of the length of the surface.
